(19) United States
(12) Patent Application Publication
(10) Pub. No.: US 2014/0041799 A1
(43) Pub. Date: Feb. 13, 2014

(54) Apparatus and Method for Laying a Protective Film Cover on the Screen of a Mobile Electronic Device

(71) Applicant: Joseph Nam, Marietta, GA (US)

(72) Inventor: Joseph Nam, Marietta, GA (US)

(21) Appl. No.: 13/569,213

(22) Filed: Aug. 8, 2012

(51) Int. Cl. H05K 13/00

(52) U.S. Cl. CPC H05K 13/00
USPC 156/247; 156/538

(57) ABSTRACT

This invention discloses an apparatus and method that can be easily used to lay a protective film cover on the screen of a mobile electronic device so that the cut-off portion on the protective film cover aligns properly on the screen of the mobile electronic device. The apparatus has a top housing component and a bottom housing component. The top and bottom housing component are joined by a main body that has a closed rear end and an open front end, into which the mobile electronic device is inserted. The internal cavity of open front end has a stopper that centralizes the mobile device when it is inserted into it. The method discloses way of laying protective film cover on the mobile electronic device so that it is aligned properly.

### BACKGROUND OF THE INVENTION

Field of invention. Embodiments of the present invention relate to an apparatus and a method for laying a protective film cover on the screen of a mobile electronic device.

Description of related art. Nowadays, mobile electronic devices are popular than ever. Most, if not all, of these mobile electronic devices have screens that are susceptible to damage in the event of a fall or the application of external force. In response to this problem, protective covers have been created to protect mobile electronic devices from damage. For example, thick plastic coverings, which practically cover the entire phone, are used to protect the screens of mobile electronic devices from damage. These plastic coverings, however, cover the entire mobile electronic device in that it covers the beauty of the phone, diminishing the mobile electronic device's aesthetic value.

More recently, though, protective covers made of film have been developed, which, in addition to protecting the screens of mobile electronic devices from damage, offer several aesthetic advantages over thick plastic covers. These protective film covers protect mobile electronic devices the same way thick plastic covers do but do not block the aesthetic appearance of the mobile electronic devices; thus the beauty of the mobile electronic device is not covered and therefore the aesthetic value of the mobile electronic device is not diminished.

To protect the mobile electronic device, the protective film cover is laid on the screen of a mobile electronic device, and it protects the screen of the mobile electronic device by absorbing the energy that happens upon the screen in the event of a fall or exertion of force. Applying a protective film cover on a mobile electronic device, however, is not as easy it appears. It is not easy because the user has to peel the bottom layer of the protective film cover so that the adhesive portion is exposed. Because a protective film cover is adapted and cut to fit the screen features on each mobile electronic device, the user often uses a “hit or miss” approach in laying the protective film cover on the screen of the mobile device. The user has to lay the adhesive portion of the protective film cover on the screen of the mobile electronic device so that the cut-off portion is aligned properly.

If the user misses, that is, the user does not properly align the cut-out portion of the protective film cover on the screen of the mobile electronic device, the user attempts to lay it again. Typically, after many failed attempts at laying the protective film cover on the screen of the mobile electronic device, several things usually happen: the adhesive portion on the protective film cover begins to wear off, dust begins to accumulate on the adhesive portion, and bubbles begin to form beneath the protective film cover and on the screen of the mobile electronic device when the user attempts to lay it again. At worst, the protective film cover is damaged and has to be discarded.

Furthermore, many mobile electronic devices, for example, mobile phones, have touchscreen capabilities and on-screen cameras. These touchscreens have touchscreen sensors that are invisible to the naked eye. If a protective film cover is not laid and aligned properly, the on-screen cameras or the touchscreen sensors may be covered, thwarting the functionality of the phone. Because of these problems, many users have to pay meticulous and strenuous attention when laying the protective film cover on the screen of their mobile electronic device so that the cut-outs on the protective film cover are aligned properly on the screen of the mobile electronic device. This could take an unusual amount of time than necessary. Elderly persons, visually-impaired individuals, or the physically challenged may be unable to lay a protective film cover on the screens of their mobile electronic device.

In response to the foregoing problems discussed, this invention discloses an apparatus and a method for seamlessly laying a protective film cover on the screen of a mobile electronic device. This invention is a cost-effective and easy way of enabling the user to properly lay the protective film cover on the screen of the mobile electronic device so that all the cut-outs on the protective film cover are aligned properly on the screen of the mobile electronic device. This invention also eliminates the problems of bubbles that are created when the protective film cover is not properly laid on the screen of the mobile electronic device. More importantly, this invention enables the user to seamlessly lay the protective film cover on the screen of the mobile electronic device such that it is aligned properly without covering the on-screen camera or the touch screen sensors on the screen of the mobile electronic device. This saves the user precious time.

### BRIEF SUMMARY OF THE INVENTION

An object of this invention is to disclose a method for laying a protective film cover on the screen of a mobile electronic device.

Another object of this invention is to disclose an apparatus for use in laying a protective film cover on the screen of a mobile electronic device.

Still another object of this invention is to disclose an apparatus and method for laying a protective film cover on the screen of a mobile electronic device such that the cut-off portion in the film protective covering is aligned properly on the screen of the mobile electronic device.

Yet another object of this invention is to disclose an apparatus and method for laying a protective film cover on the screen of a mobile electronic device such that there are no bubbles formed when the protective film cover is laid on the screen of the mobile electronic device.

To achieve the foregoing objectives, this invention discloses an apparatus and a method for applying a protective film cover on the screen of a mobile electronic device. The apparatus is rectangular in shape and has an open receptacle into which a mobile electronic device can be inserted. The apparatus can be adapted to each mobile electronic device so that it will fit accordingly. The protective film cover is positioned on the apparatus such that when the mobile electronic device is inserted into the receptacle of the apparatus, the protective film cover can be easily laid on the mobile electronic device, eliminating the need for manually and strenuously applying the film protective covering over the mobile electronic device.

The method for laying a protective film cover on the screen of a mobile electronic device, disclosed in this application, involves the steps of wiping the screen of the mobile electronic device with a cloth, pre-positioning the bottom end of said protective film cover on the top end of said apparatus; raising said protective film cover with a tape 3 and sliding said apparatus and said pre-positioned protective film cover into the bottom end of said mobile electronic device so that it fits tightly; raising said protective film cover and removing the bottom layer of said protective film cover so that the adhesive portion of said protective film cover is exposed; laying said adhesive portion of said protective film cover on said screen of said mobile electronic device; peeling the bottom part 4b of the bottom end tape 4 from the apparatus 5b of the tape so that the mobile electronic device can be removed out of the apparatus freely; sliding the mobile electronic device out of the apparatus 5b; peeling the tape 4 from the protective film cover; and pressing the protective film cover 5 against the screen of the mobile electronic device firmly.

The above disclosed objects of this invention will become apparent upon a review of the specification and accompanying drawings.

### DEFINITION OF TERMS

Not Applicable

### BRIEF DESCRIPTION OF SEVERAL DRAWINGS OF THE INVENTION

FIG. 1A is a diagram of the top view of the apparatus.

FIG. 1B is a diagram of the side view of the apparatus.

FIG. 1C is a diagram of the perspective view of the apparatus

FIG. 2A depicts the top view of the apparatus when protective film cover has been positioned on the apparatus, but before the mobile electronic device has been inserted.

FIG. 2B depicts the side view of the apparatus when protective film cover has been positioned on the apparatus, but before the mobile electronic device has been inserted.

FIG. 3 depicts a perspective view of the apparatus when the protective film cover has been properly positioned on the apparatus. The bottom end of the protective film cover is attached to the top end of the apparatus with a tape and has been slightly raised from the top portion of the apparatus, in preparation for sliding the receptacle in the apparatus in the bottom end of the mobile electronic device until it fits tightly. The arrow in the diagram shows the direction of the sliding.

FIG. 4A depicts the top view of the apparatus and the protective film cover after they have been slid into the mobile electronic device and fit snug in the bottom end of the mobile electronic device. The mobile electronic device has been inserted and the protective film cover has been layered on the screen of the mobile electronic device.

FIG. 4B depicts the side view of the apparatus and an elevated protective film cover after they have been slid into the mobile electronic device and fit snug in the bottom end of the mobile electronic device.

FIG. 5A is a diagrammatic representation of the length of the apparatus. More importantly, the diagram shows that the open end of the apparatus (the distance between 8 and 9) is equivalent to the maximum width of the mobile electronic device inserted into it. It also shows the midpoint 7 of the apparatus, a point at which the stopper is positioned. The stopper receives and centers the mobile electronic device.

FIG. 5B is a diagram of the apparatus when the mobile electronic device has been inserted into it and an elevated protective film cover that has been placed on the top of the apparatus.

FIG. 5C is a diagram of another embodiment of the apparatus, which is adapted for an eclipse-shaped mobile electronic device. The top end of the apparatus also shows an eclipse-shaped wall (11, 12), on which an eclipse-shaped protective film cover will be placed.

FIG. 6A is a diagram of the top end of the apparatus. More importantly, it shows the enclosure 14 formed by the three vertical edges (13, 15, and 16) on the top end of the apparatus. The enclosure will receive the protective film cover 17 when the protective film cover is slid in the enclosure in the direction shown in the diagram.

FIG. 6B is a diagram showing a close view of one of the vertical edges 18 that is on the top end of the apparatus.

FIG. 7 is a diagram of the stopper that will be placed in the internal cavity of the apparatus.

FIG. 8 is a diagram of a protective film cover that has been fitted into the enclosure on the top end of the apparatus. Most importantly, FIG. 8 shows how the protective film cover will fit in captivity in the enclosure created by vertical edges on the top end of the apparatus. In addition, FIG. 8 shows how the mobile electronic device will fit into the apparatus when the protective film cover has been fitted in the enclosure on the top end of the apparatus.

### DETAILED DESCRIPTION OF THE INVENTION

### Description of the Preferred Embodiment

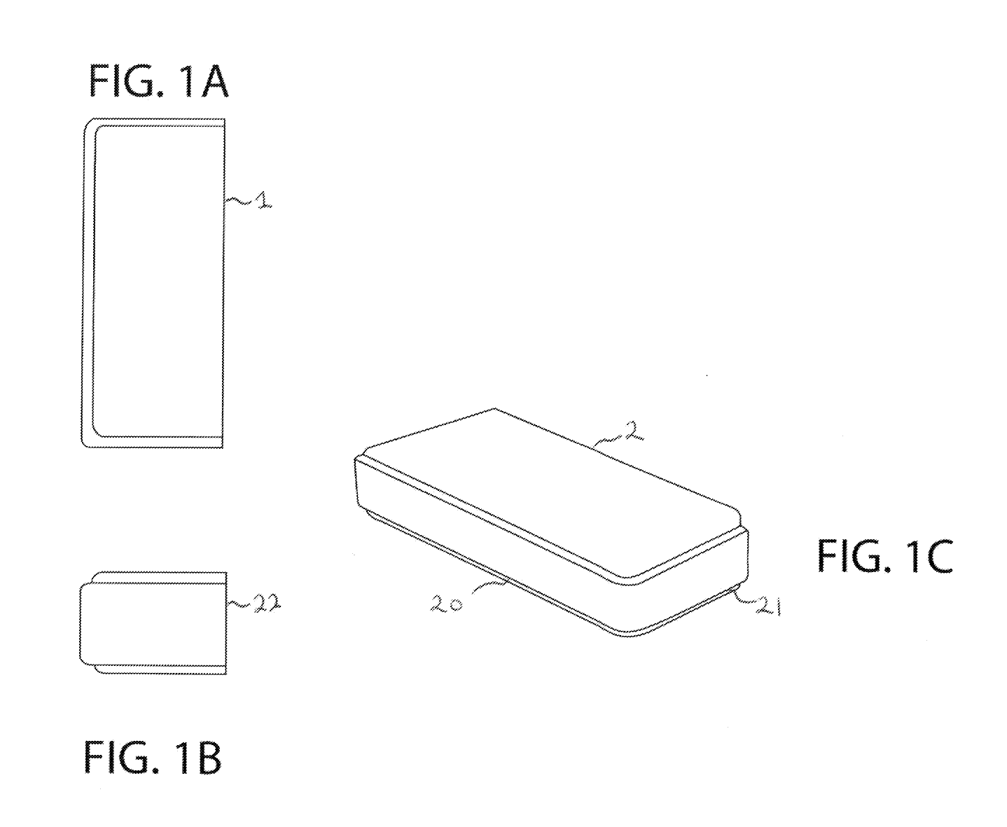

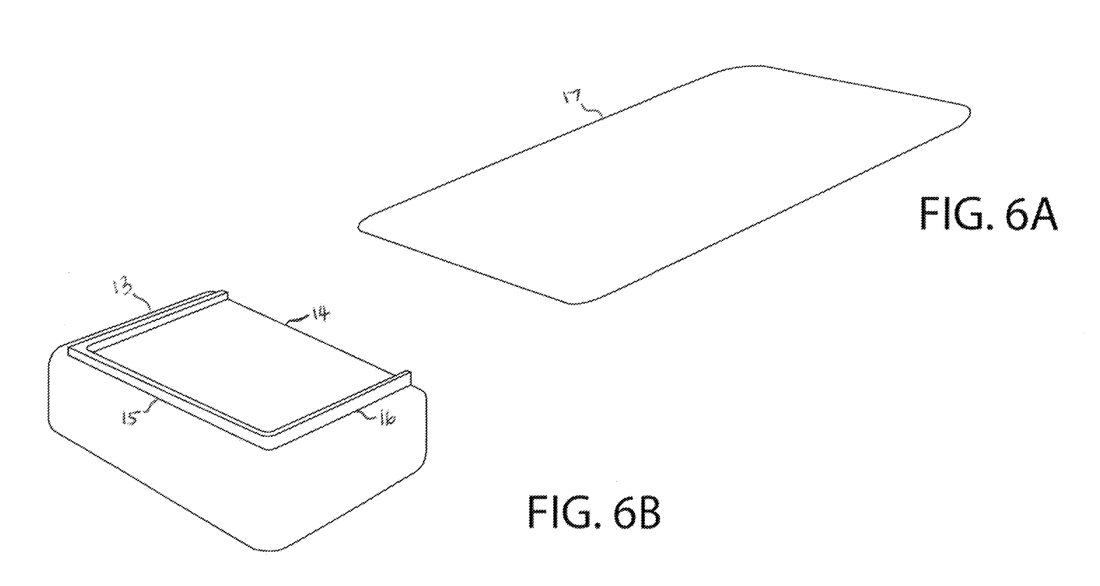

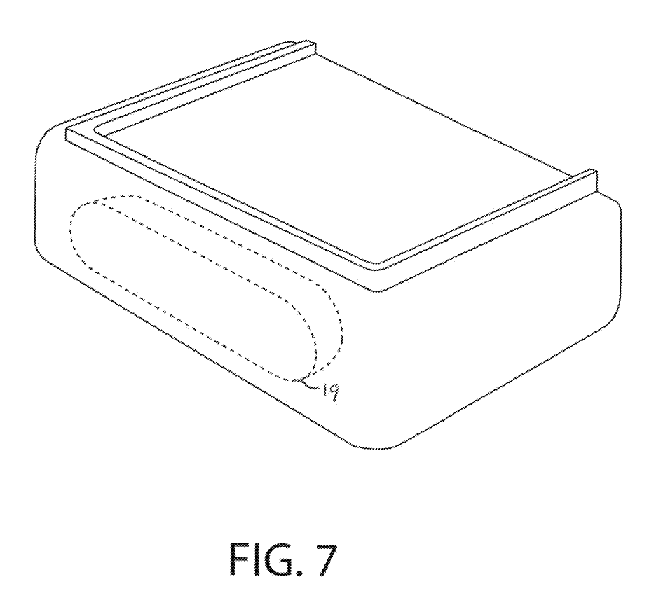

An apparatus and method for laying a protective film cover on the screen of a mobile electronic device is disclosed. The preferred embodiment of the apparatus is disclosed in FIGS. 1A, 1B, 1C, 6A, and 81A, 1B, 1C, 6A, and 8. The apparatus is made from a polymer consisting of polystyrene, rubber, polyvinyl chloride, and nylon. The apparatus is rectangular in shape and has a rectangular top housing component 1, 2 and a rectangular bottom housing component. The rectangular top housing component and the bottom housing component are joined together by an intervening main body 20 that has two sides on opposite ends of each other 21, 22, as shown in FIG. 1C. The rear of the intervening main body 20 is a closed end, but the front of the horizontal main body is an open end, into which the mobile electronic device is inserted. A stopper 19 is positioned in the internal cavity of the apparatus at point 7. The stopper 19 is at the far end inside 7 of the mobile electronic device, and its purpose is to stop and centralize the mobile electronic device when the mobile electronic device is inserted into the open front end of the apparatus. The stopper 19 is cylindrical in shape.

When the mobile electronic device is inserted into the open front end and pushed to the end of the apparatus, it is received by the stopper 19, which centralizes the mobile electronic device 7. The stopper is critical to this invention because it centralizes the mobile device. A centralized mobile device will enable the protective film cover to be properly aligned on the mobile electronic device. The length of the apparatus is determined by the type of mobile electronic device the apparatus was created for. The length of the open front end of the apparatus is equivalent to the maximum width of the mobile electronic device the apparatus is designed for.

The top housing component of the apparatus has a plurality of vertical edges 13, 15, and 16, forming an enclosure 14, on which the protective film cover 17 will be held in captivity. The plurality of vertical edges are three vertical edges, one on the rear 15 of the top end of the apparatus, one on the left side 13 of the top end of the apparatus, and one on the right side 16. The enclosure 14 will ensure that the protective film cover 17 is uniformly positioned and held captive in the enclosure 14 on the top housing component of the apparatus. The protective film cover can be attached to the top end of the apparatus with a tape 4 or any means for attaching a film to an apparatus.

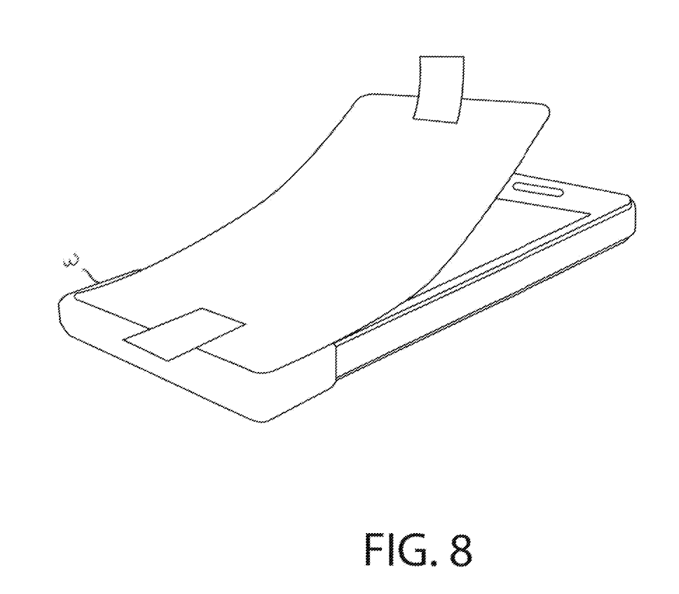

The protective film cover will fit in captivity in the enclosure on the top end of the apparatus, as shown in FIG. 8. It is also important to know that the width w of the apparatus, as shown in FIG. 8, is such that it will not be longer than 3/10 of the length of the mobile electronic device. As shown in FIG. 8, the protective film cover used with this apparatus will have a bottom adhesive component that can be exposed when peeled. As shown in FIG. 8, the part of the protective film cover that lies on the apparatus already has the adhesive portion exposed on the apparatus, while the part of the protective film cover that does not lie on the apparatus does not have its adhesive portion exposed. The adhesive portion is exposed by peeling the bottom of the protective film cover.

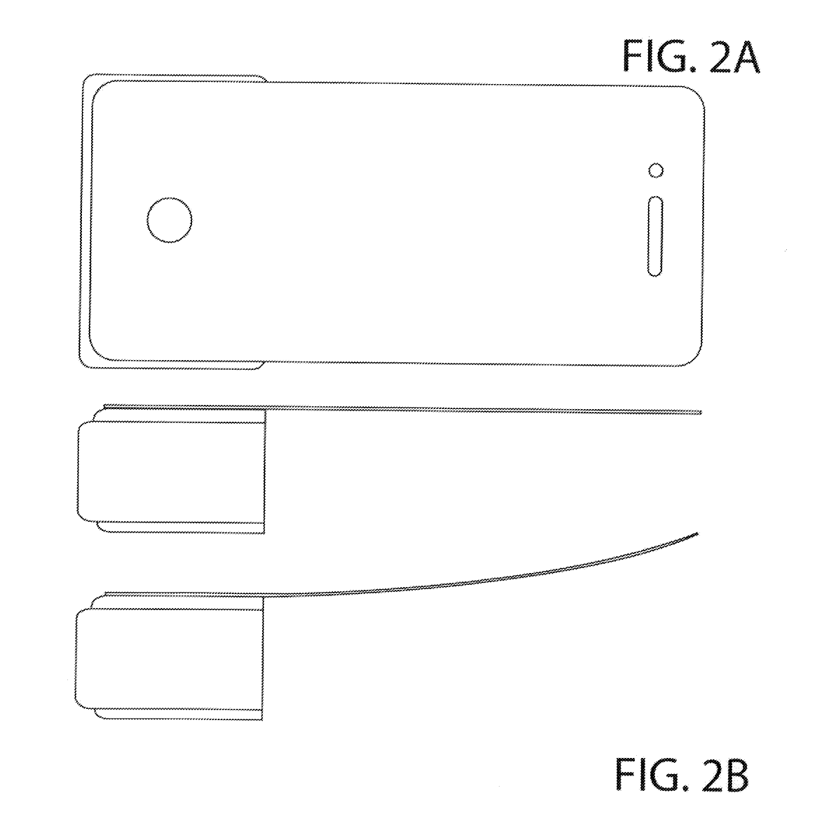

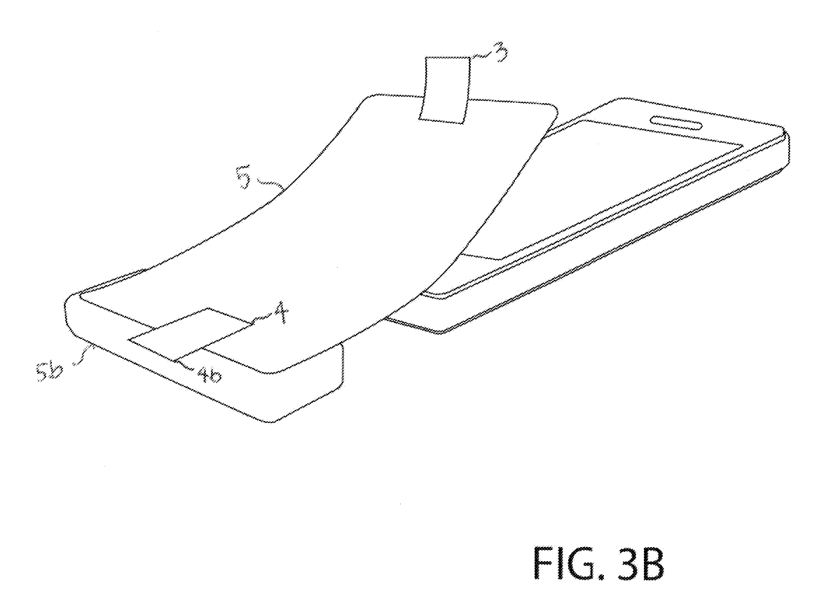

A method of using the apparatus to lay a protective film cover on the screen of a mobile electronic device is also disclosed as part of this invention. The protective film cover is pre-positioned on the top part of the apparatus as shown in FIGS. 2A and 2B. The protective film cover has a bottom end and a top end. The bottom end of the protective film cover is attached to the top of the apparatus with a tape 4, while the top end of the protective film cover has a tape 3. Using the tape 3, the protective film cover is slightly raised from the apparatus so as to expose the open end of the apparatus, into which the bottom end of the mobile electronic device will be inserted.

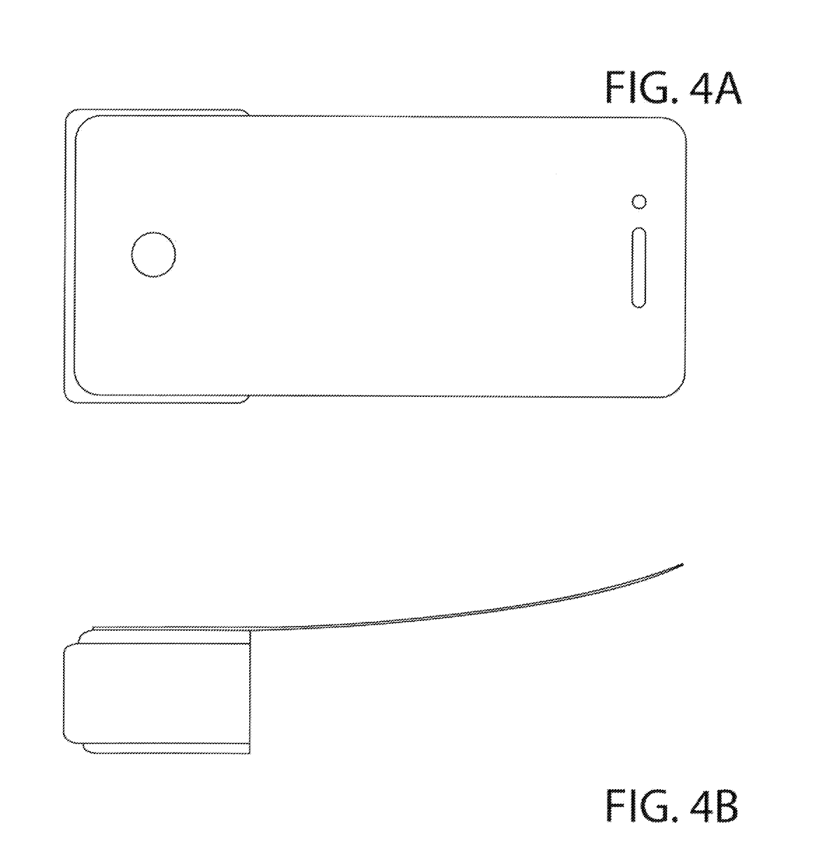

While the protective film cover 5 is raised, the open end of the apparatus is then slid into the bottom end of the mobile electronic device until it snugs tightly, as shown in FIG. 4B. The bottom layer of the protective film cover is then peeled off so that the adhesive portion of the protective film cover is exposed, and, using the tape 3, the adhesive portion of the protective film cover is laid on the screen of the mobile electronic device. The bottom part 4b of the tape 4 is now peeled from the apparatus 5b and the apparatus is gently removed from the mobile electronic device, leaving a protective film cover that has been properly aligned on the screen of a mobile electronic device. Tape 4 is now finally removed from the protective film cover 5, and the user can now use his fingers to firmly press the protective film cover against the screen of the mobile electronic device.

It should be noted that this method is applicable to the preferred embodiment, in that the apparatus has an enclosure 14 on its top end and the protective film cover is can only be raised to the extent that the enclosure allows it to be raised. FIG. 8 shows that only 7/10 of the protective film cover can be raised because the enclosure 14 on the top of the apparatus will prevent 3/10 of the protective film cover from being elevated. Thus 3/10 of the protective film cover is exposed only after the apparatus has being slid out of the mobile electronic device, which is when the user can lay the remaining 3/10 of the protective film cover on the mobile electronic device.

### Description of Additional Embodiments

This invention should not be restricted to the scope of the preferred embodiment. A person having ordinary skill in the art could create additional embodiments of this invention without departing from the scope and spirit of this invention. For instance, in an alternative embodiment, an enclosure can be formed on the top of the apparatus by having a depressed region on the top of the apparatus. The enclosure formed by the depressed region will be sized to fit each applicable protective film cover. Similar to the enclosure 14 formed by the plurality of vertical edges (13, 15, and 16) this depressed region will ensure that the protective film cover is held in captivity and uniformly placed on top of the apparatus at all times.

In a related embodiment, the apparatus is sized to fit any mobile phone, tablet pc, such as an Ipad, or a mobile electronic device that has a screen. Even though the preferred embodiment discloses that the width of the apparatus is no more than 3/10 of the length of the mobile electronic device, a person having ordinary skill in the art could extend the width of the apparatus so that it is at least ⅕ of the length mobile electronic device to ⅘ of the length of the mobile electronic device.

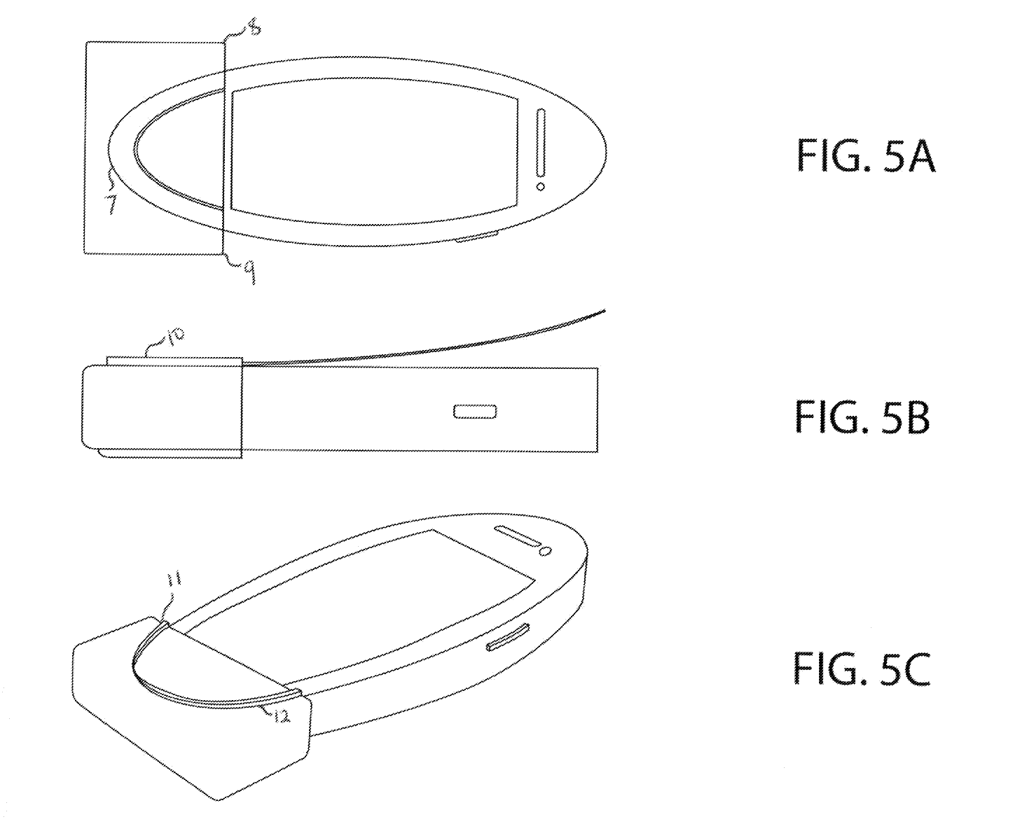

FIGS. 5A and 5C show yet another embodiment of the apparatus. They show that the apparatus can be adapted to fit a concave-shaped mobile electronic device. A concave-shaped enclosure is formed on the top of the apparatus, as shown in FIG. 5C, on which a concave-shaped protective film cover will be laid.

In another related embodiment, the internal cavity in the apparatus is fitted with a plurality of edges, whose purpose is to guide the mobile electronic device to a stationary and fixed position when the internal cavity receives the mobile electronic device.

In yet another related embodiment, the stopper 19 that is fitted in the internal cavity of the mobile electronic device could be rectangular, square, or shaped in any form so long as it receives and centralizes the mobile electronic device.

In another related embodiment, the apparatus comes already fitted with a protective film cover and ready for use with a mobile electronic device.

In yet another related embodiment, the apparatus is bare without any protective film cover, but the top end of the apparatus is marked with a line so as to communicate to the user the position at which to place a protective film cover and facilitate proper alignment when the protective film cover is laid.

The mobile electronic device could be any mobile phone or tablet pc, and nothing should be construed as limiting a person having ordinary skill in the art from adapting this apparatus to work with any other mobile electronic device that has a screen. A person having ordinary skill in the art may modify the apparatus to different shapes and sizes so that a user can use the apparatus to lay a protective film cover on the screen of a mobile electronic device or on the screen of a device that has a screen desired to be protected.

There are several methods that could be used to lay a mobile electronic device on the screen of a mobile electronic device, depending on the apparatus. For example, the following method is applicable to an apparatus that does not have a plurality of vertical edges or enclosure, that is, the protective film cover is laid on the apparatus through marks that have been placed on the apparatus indicating the position at which the protective film cover should be placed: The protective film cover is pre-positioned on the top part of the apparatus as shown in FIGS. 2A and 2B. The protective film cover has a bottom end and a top end. The bottom end of the protective film cover is attached to the top of the apparatus with a tape 4, while the top end of the protective film cover has a tape 3. Using the tape 3, the protective film cover is raised completely from the apparatus so as to expose the entire bottom end of the protective film cover and the open end of the apparatus, into which the bottom end of the mobile electronic device will be inserted.

While the protective film cover 5 is raised all the way up, the open end of the apparatus is then slid into the bottom end of the mobile electronic device until it snugs tightly. The entire bottom layer of the protective film cover is then peeled off so that the adhesive portion of the protective film cover is exposed, and, using the tape 3, the adhesive portion of the protective film cover is laid on the screen of the mobile electronic device. The user now uses his fingers to press the protective film cover on the screen of the mobile electronic device.

The bottom part 4b of the tape 4 is now peeled from the apparatus 5b, and the apparatus is gently removed from the mobile electronic device, leaving a protective film cover that has been properly aligned on the screen of a mobile electronic device. Tape 4 is now finally removed from the protective film cover 5, and the user can again use his fingers to firmly press the protective film cover against the entire screen of the mobile electronic device. It should be noted that in this method, the entire bottom layer of the protective film cover can be peeled when the protective film cover is raised, unlike the method disclosed in the preferred embodiment, where only 7/10 of the protective film cover is raised and can be peeled.

The invention claimed is

1. An apparatus for use in laying a protective film cover on the screen of a mobile electronic device, comprising:
a. a rectangular top housing component, a rectangular bottom housing component, and an intervening longitudinal main body having two sides that are on opposite ends of said intervening longitudinal main body; and
b. said rectangular top housing component being joined to said rectangular bottom housing component by said intervening longitudinal main body such that said intervening main body has a closed rear end and an open front end.

2. An apparatus as in claim 1, wherein the material of said apparatus is made from a group consisting of polystyrene, polyvinyl chloride, nylon, and rubber.

3. An apparatus as in claim 1, wherein the internal cavity of said open front end in said intervening longitudinal main body is fitted with a stopper that centralizes the mobile electronic device when said internal cavity receives the mobile electronic device.

4. An apparatus in claim 1, wherein the width w of the apparatus does not exceed 3/10 of the length of said mobile electronic device.

5. An apparatus in claim 1, wherein the length of said open front end is equivalent to the maximum width of the mobile electronic device that is inserted into said open front end.

6. An apparatus as in claim 1, further comprising a plurality of vertical edges on the surface of said rectangular top housing component, said vertical edges creating an enclosure on which the protective film cover will be positioned.

7. An apparatus as in claim 1, wherein the bottom end of said protective film cover attached the top end of said apparatus by means for attaching.

8. A method for using the apparatus to lay a protective film cover on the screen of a mobile electronic device, comprising the following steps:
a. pre-positioning the bottom end of said protective film cover on the top end of said apparatus;
b. raising said protective film cover with a tape 3 and sliding said apparatus and said pre-positioned protective film cover into the bottom end of said mobile electronic device so that it fits tightly;
c. raising said protective film cover and removing the bottom layer of said protective film cover so that the adhesive portion of said protective film cover is exposed;
d. laying said adhesive portion of said protective film cover on said screen of said mobile electronic device;
e. peeling the bottom part 4b of the bottom end tape 4 from the apparatus 5b of the tape so that the mobile electronic device can be removed out of the apparatus freely;
f. sliding the apparatus 5b out of the mobile electronic device;
g. peeling the tape 4 from the protective film cover; and
h. pressing the protective film cover 5 against the screen of the mobile electronic device firmly.
